(19) United States
(12) Patent Application Publication
(10) Pub. No.: US 2025/0054753 A1
(43) Pub. Date: Feb. 13, 2025

(54) SUBSTRATE PROCESSING METHOD

(71) Applicant: ASM IP Holding B.V., Almere (NL)

(72) Inventors: KiHun Kim, Yongin-si (KR); SangHeon Yong, Yongin-si (KR); Sungha Choi, Suwon-si (KR); JuHyuk Park, Hwaseong-si (KR); Jihye Yang, Ansan-si (KR); Jaewoo Jeong, Tokyo (JP); Shinya Yoshimoto, Tokyo (JP); Makoto Igarashi, Tokyo (JP)

(21) Appl. No.: 18/795,432

(22) Filed: Aug. 6, 2024

Related U.S. Application Data
(60) Provisional application No. 63/531,387, filed on Aug. 8, 2023.

(51) Int. Cl. H01L 21/02; C23C 16/34; C23C 16/505; C23C 16/56

(52) U.S. Cl. CPC H01L 21/02348; C23C 16/345; C23C 16/505; C23C 16/56; H01L 21/02164; H01L 21/0217; H01L 21/02208; H01L 21/0223

(57) ABSTRACT

Provided is a method of filling a gap with a flowable oxide film. In one embodiment of the disclosure, the method comprises forming a flowable silicon nitride film, followed by converting the silicon nitride film in a silicon oxide film. The silicon nitride film may be formed by supplying an oligomeric silicon source and a nitrogen source activated by a power. The silicon nitride film may be converted into the silicon oxide film by supplying an oxygen source while applying a vacuum UV radiation. The vacuum UV radiation may be applied in a pulsed mode.

### CROSS-REFERENCE TO RELATED APPLICATIONS

This application claims priority to U.S. Provisional Patent Application Ser. No. 63/531,387 filed Aug. 8, 2023 titled SUBSTRATE PROCESSING METHOD, the disclosure of which is hereby incorporated by reference in its entirety.

### FIELD OF INVENTION

The disclosure relates to a method of filling a gap, more particularly to a method of filling a gap with a flowable dielectric film using a Vacuum UV radiation.

### BACKGROUND OF THE DISCLOSURE

There are some methods to fill gaps with high aspect ratio in manufacturing microelectronics devices. A conventional PECVD method forms a thick film profile at the upper portion of the gap. A conventional PEALD method leaves a seam or a void at a center portion of the gap because films growing on both side walls of the gap meet each other, making it easy to leave a seam therebetween.

A flowable PECVD method has a benefit that it does not leave a seam or a void in the film. The flowable film filling the gap needs to be hardened in order to be converted into a solid film. To that end, an annealing at high temperature or a UV radiation in a steam atmosphere have been utilized. The high temperature annealing is conducted at over 700° C., but it results in an undesirable high thermal budget. With the UV radiation in the steam atmosphere, hardening of the film is limited to the surface region and the conversion of the film is not uniform. The UV radiation also requires a long curing time (hardening time) for desired film properties, leading to low through-put.

Thus, a new approach of hardening the flowable film quickly and uniformly by depth at low temperature is required.

### SUMMARY OF THE DISCLOSURE

The disclosure discloses relates to a method of filling a gap, more particularly to a method of filling a gap with a flowable dielectric film using a Vacuum UV radiation.

In one or more embodiments, a method of forming a film on a pattern substrate, the method may comprise forming a flowable silicon nitride film in the gap at a first temperature comprising: supplying a silicon-containing gas and a nitrogen-containing gas to a reaction chamber and applying a power to the reaction chamber and activating the nitrogen-containing gas in which the silicon-containing gas may react with the activated nitrogen-containing gas and the silicon nitride film may be formed, and converting the silicon nitride film into a silicon oxide film at a second temperature comprising: supplying an oxygen-containing gas to the reaction chamber and converting the silicon nitride film into the silicon oxide film in which a Vacuum UV radiation may be applied while supplying the oxygen-containing gas.

In one or more embodiments, the Vacuum UV radiation may be applied for 10 minutes or less.

In one or more embodiments, the Vacuum UV radiation may be applied in a pulsed mode and a duty ratio of the pulsed mode may be 20% or less.

In one or more embodiments, an intensity of the Vacuum UV radiation may be in a range of between about 80 mW/cm² and about 120 mW/cm².

In one or more embodiments, the first temperature may be between about 20° C. and about 100° C. or between about 40° C. and about 70° C.

In one or more embodiments, the second temperature may be between about 70° C. and about 150° C. or between about 80° C. and about 120° C.

In one or more embodiments, the silicon nitride film may comprise at least one of SiN, SiCN, or a mixture thereof.

In one or more embodiments, the silicon-containing gas may comprise at least one of dimer-trisilylamine, trimer-trisilylamine, tetramer-trisilylamine, pentamer-trisilylamine, hexamer-trisilylamine, heptamer-trisilylamine, octamer-trisilylamine, 2,2,4,4,6,6-hexamethylcyclotrisilazane, 1,1,1,3,3,3-hexamethyl disilazane, 1,3-divinyl-1,1,3,3-tetramethyldisilazane and 1,1,3,3-tetramethyldisilazane, or a mixture thereof.

In one or more embodiments, the nitrogen-containing gas may comprise at least one of NH₃, NH₄, N₂H₂, N₂H₄, or a mixture thereof.

In one or more embodiments, the silicon oxide film may comprise at least one of SiO, SiCO, or a mixture thereof.

In one or more embodiments, the oxygen-containing gas may comprise at least one of O₂, O₃, or mixture thereof.

The Vacuum UV radiation may be applied in another reaction chamber after transferring the substrate thereto from the reaction chamber in which the silicon nitride film may be converted into the silicon oxide film, while supplying the oxygen-containing gas therein.

In one or more embodiments, the power is in a range of between about 40 W and about 200 W or between about 50 W and about 150 W.

In one or more embodiments, the method may further comprise performing a film densification to densify the silicon oxide film at a third temperature in a reaction chamber different from the reaction chambers in which the film is formed and converted, while supplying a treatment gas thereto.

In one or more embodiments, the film densification may be performed by at least one of a plasma treatment, a thermal treatment, or a mixture thereof.

In one or more embodiments, the third temperature may be between about 50° C. and about 800° C. or between about 100° C. and about 600° C.

In one or more embodiments, the treatment gas may comprise at least one of inert gas, O₂, O₃, H₂O, H₂O₂, N₂, or a mixture thereof during the thermal treatment.

In one or more embodiments, the treatment gas may comprise at least one of H₂, He, or a mixture thereof during the plasma treatment.

In one or more embodiments, a power of between about 300 W and about 700 W may be applied to the reaction chamber during the plasma treatment.

In one or more embodiments, a method of filling a gap of a substrate is disclosed. The method may comprise forming a flowable silicon nitride film in the gap comprising: supplying a silicon-containing gas and a nitrogen-containing gas to a reaction chamber; and applying a power to the reaction chamber to activate the nitrogen-containing gas, wherein the silicon-containing gas may react with the activated nitrogen-containing gas to form the silicon nitride film, converting the silicon nitride film into a silicon oxynitride film (SiON) while supplying an oxygen-containing gas to the reaction chamber; and applying a Vacuum UV radiation to the silicon oxynitride film.

In one or more embodiments, the method may be performed at about 70° C. or below.

In one or more embodiments, the oxygen-containing gas may comprise an ozone (O₃).

In one or more embodiments, a concentration of the ozone may be in a range of between about 200 g/m³ and about 400 g/m³.

In one or more embodiments, the method may further comprise treating the silicon oxynitride film thermally or applying a power while supplying at least one of Ar, O₂, N₂, or the mixture thereof.

In one or more embodiments, a wet etch rate of the silicon oxynitride film may be determined by a ratio of a time for converting the silicon nitride film into the silicon oxynitride film to a time for treating the silicon oxynitride film under the Vacuum UV radiation.

In one or more embodiments, the wet etch rate of the silicon oxynitride film may be about 15 nm/minute at the ratio of 1:1.

In one or more embodiments, the power may be in a range of between about 10 W and about 1,000 W.

In one or more embodiments, an intensity of the Vacuum UV radiation is in a range of between about 80 mW/cm² and about 120 mW/cm².

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a substrate processing method according to the embodiment of the present disclosure.

FIG. 2 illustrates a substrate processing method according to another embodiment of the present disclosure.

FIG. 3 illustrates a timing graph for the substrate processing method according to the embodiment of the present disclosure.

FIG. 4 illustrates a timing graph for the substrate processing method according to the embodiment of the present disclosure.

FIG. 5 illustrates a timing graph for the substrate processing method according to the embodiment of the present disclosure.

FIG. 6A illustrates a molecular structure of dimer-TSA silicon source.

FIG. 6B illustrates a molecular structure of trimer-TSA silicon source.

FIG. 7 illustrates a reaction mechanism of the method according to the embodiment of the present disclosure.

FIG. 8 illustrates the definition of duty ratio.

FIGS. 9A to 9E illustrate a flowable gap fill process according to the embodiment of the present disclosure.

FIG. 10 illustrates an IR (Infrared Spectroscopy) analysis data showing a film composition according to the conversion conditions.

FIG. 11 illustrates an XPS (X-ray Photoelectron Spectroscopy) analysis data showing a film composition according to the embodiment of the present disclosure.

FIG. 12 illustrates a wet etch rate of SiO film depending on the thermal treatment conditions.

FIG. 13 illustrates a wet etch rate ratio (WERR) of SiO film depending on the thermal treatment conditions.

FIG. 14 illustrates an Infrared Spectroscopic Analysis results showing a bonding structure of the SiO film depending on the thermal treatment conditions at 450° C.

FIG. 15 illustrates a substrate processing method according to another embodiment of the present disclosure.

FIG. 16 illustrates a timing graph of for the substrate processing method to form a silicon oxynitride film according to an embodiment of the present disclosure.

FIG. 17 illustrates a wet etch rate of a silicon oxynitride film according to a ratio of the conversion time in ozone (O₃) to the Vacuum UV radiation treatment time.

FIG. 18 illustrates an Infrared Spectroscopy Analysis results showing a bonding structure of a silicon oxynitride film formed according to an embodiment of the present disclosure.

FIG. 19 illustrates an etch selectivity between a silicon oxynitride film and a silicon oxide film depending on an etch condition.

FIG. 20 shows a Scanning Electron Microscopy (SEM) image of SiON film filling a gap.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

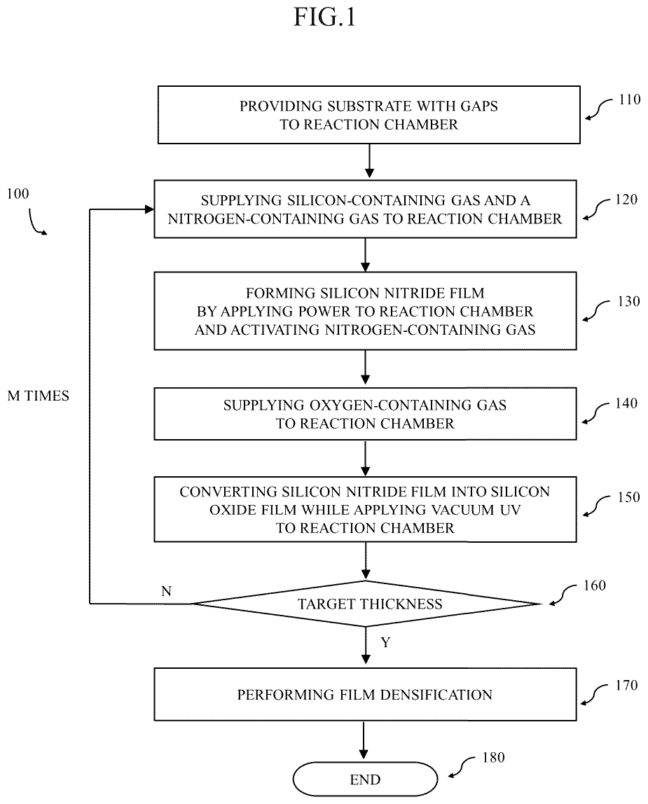

FIG. 1 illustrates a substrate processing method according to the embodiment of the present disclosure.

In the step 110 of the substrate processing method 100, a substrate may be provided to a reaction chamber. In more detail, the substrate may be loaded onto a susceptor mounted on a heating block. The heating block may provide a heat energy to heat the substrate to a process temperature. The substrate may have a semiconductor circuit formed thereon including 3D structures and gaps. In some embodiment of the present disclosure, the depth of the gap may be 200 nm or less. The reaction chamber may comprise an equipment in which the substrate is processed. In the reaction chamber, a deposition, a gap fill, an etch, or any other substrate processing process using a gas activation source such as plasma and/or UV may be performed on the substrate.

In the step 120, a silicon-containing gas as a silicon source and a nitrogen-containing gas as a nitrogen source may be supplied to a reaction chamber. The silicon-containing gas may comprise an oligomeric silicon source having a flowability.

In the step 130, a power may be applied to the reaction chamber to activate the nitrogen-containing gas. The activated nitrogen-containing gas may react with the silicon-containing gas to form a flowable silicon nitride film. The steps 120 and 130 may be carried out at a first temperature.

In the steps 120 and 130, when the molecular structure of the supplied silicon source is too simple, for example, when the silicon source is a monomer or a single molecule, a vapor pressure thereof may be high. Thus, the silicon source may get volatilized easily, and accordingly, the silicon source may lose the flowability.

On the other hand, when the molecular structure of the silicon source is complicated, a molecular weight thereof is large and thus the vapor pressure thereof is low, so the flowability of the silicon source may be too low. Thus, the process efficiency may be lowered in a process that requires the flowability above an appropriate magnitude. For example, when a flowable film is used to fill the gap and the degree of flowability of the flowable film is insufficient, a void may occur in the gap.

Therefore, as a silicon source used in example embodiments of the present disclosure, an oligomeric silicon source having a molecular structure that is not excessively simple and not excessively complicated, for example, having 2 to about 10 chain structures, may be used. The oligomeric silicon source may comprise, for example, dimer-trisilylamine (TSA), trimer-TSA, tetramer-TSA, pentamer-TSA, hexamer-TSA, heptamer-TSA, octamer-TSA, or another trisilylamine.

In some embodiments, the oligomeric silicon source may be supplied alone to the reaction chamber, respectively, and for instance, dimer-TSA as the silicon source may be supplied alone to the reactive space, and in other embodiments, trimer-TSA as the silicon source may be supplied alone to the reaction chamber. In addition, in some embodiments, two or more kinds of oligomeric silicon sources may be supplied together to the reaction chamber. For instance, in some embodiments, dimer-TSA and trimer-TSA may be simultaneously supplied as the silicon sources, in some other embodiments, trimer-TSA and tetramer-TSA may be simultaneously supplied as the silicon sources, and in yet other embodiments, dimer-TSA, trimer-TSA, and tetramer-TSA may be simultaneously supplied to the reaction chamber.

In some embodiments, the silicon-containing gas may comprise a silazane silicon source. For instance, 2,2,4,4,6,6-hexamethylcyclotrisilazane, 1,1,1,3,3,3-hexamethyl disilazane, 1,3-divinyl-1,1,3,3-tetramethyldisilazane, 1,1,3,3-tetramethyldisilazane, or a mixture thereof may be supplied as a silicon source to the reaction chamber.

On the other hand, the nitrogen-containing gas as a nitrogen source may comprise at least one of N₂, N₂O, NO₂, NH₃, NH₄, N₂H₂, N₂H₄, or a mixture thereof. The nitrogen source may be suppled at between about 10 sccm and about 100 sccm, or more specifically between about 20 sccm and about 50 sccm. The nitrogen source may be activated by a power and may further comprise nitrogen-containing radicals.

In the steps 120 and 130 of FIG. 1, a silicon nitride film may be formed by applying a power to the reaction chamber and activate the nitrogen source. The power may be in a range of between about 40 W and about 200 W, or more specifically between about 50 W and about 150 W. The activated nitrogen source may react with the silicon source and form a silicon nitride film. The silicon nitride film may comprise at least one of SiN, SiCN, or a mixture thereof.

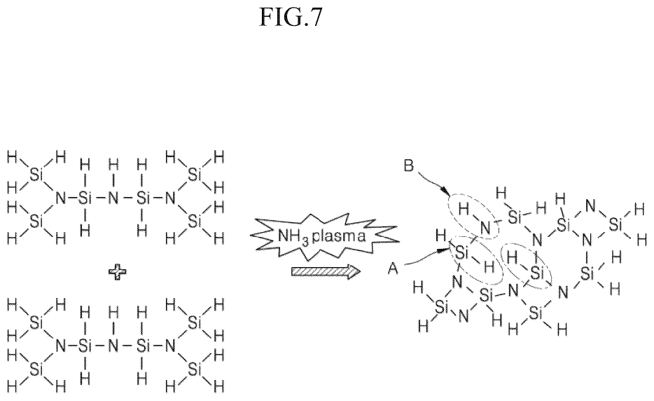

The silicon nitride film may be formed by the reaction mechanisms of oligomerization and condensation. The oligomeric silicon source supplied to a substrate may flow on the substrate, and when flowing, bonds may occur between the oligomeric source molecules to form a structure that has at least about 10 chain structures. This is called oligomerization. The oligomerization may be facilitated through the condensation reaction between the oligomeric source molecules. In the condensation reaction, a hydrogen atom may be removed as a reaction by-product from a Si—H bond of the silicon source. The oligomers bonded through the condensation reaction may form a cross-linking structure through the cross-linking while flowing within the silicon nitride film having flowability. The reaction mechanism of the oligomerization and the condensation will be described in more detail in FIG. 7 later.

The steps 120 and 130 of FIG. 1 may be carried out at a first temperature in which the flowability of the silicon source may be maintained. In some embodiments, the steps 120 and 130 may be carried out at 100° C. or less, or more specifically between about 30° C. and about 70° C.

In the step 140, an oxygen-containing gas as an oxygen source may be supplied to the reaction chamber. The oxygen source may comprise at least one of O₂, O₃, or a mixture thereof. The supplied oxygen source may infiltrate into the silicon nitride film, leading to converting the silicon nitride film into the silicon oxide film. The silicon oxide film may comprise at least one of SiO, SiCO, or a mixture thereof.

In the step 150, a vacuum UV radiation may be applied to the silicon nitride film while the oxygen-containing gas is supplied continuously in order to improve the conversion efficiency into silicon oxide film. The steps 140 and 150 of FIG. 1 may be carried out at a second temperature.

The vacuum UV is defined as a UV in vacuum or near-vacuum pressure zone. The UV in those pressure zone is known to have a wavelength shorter than 200 nm wavelength and is strongly absorbed by oxygen molecules, compared to the UV with different range of wavelength. In other words, the vacuum UV radiation may strongly excite the oxygen source and induce a high density of active oxygen. Therefore, the photo-conversion efficiency into the oxide film in oxygen atmosphere may be significantly improved, and the stoichiometry of the oxide film may be improved.

However, in the embodiment of the present disclosure, since the vacuum UV radiation is applied while supplying an oxygen-containing gas, it is required that the substrate processing is carried out at low process pressure for UV to have a wavelength range of the vacuum UV. Preferably, the process pressure may be 100 Torr or less. For instance, the steps 140 and 150 of FIG. 1 may be carried out at 100 Torr or less.

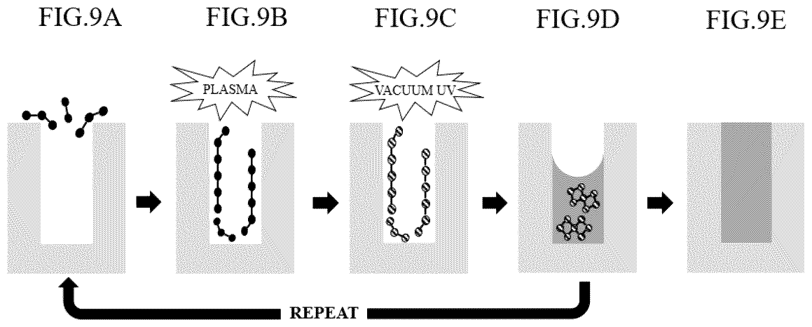

Therefore, using the vacuum UV radiation in oxygen atmosphere may have a technical benefit that the conversion of the silicon nitride film into the silicon oxide film may be further facilitated. Also, using the vacuum UV radiation may reduce the time for the oligomerization and the time for the condensation in comparison to a conversion carried out in an O₃ atmosphere without the vacuum UV as shown in FIG. 9 and Table 1 later. Therefore, a substrate processing time (e.g., throughput) may be improved.

On the other hands, when applying the vacuum UV radiation, an intensity thereof may be in a range of between about 80 mW/cm² and about 120 mW/cm².

The steps 140 and 150 for conversion may be carried out at a second temperature. In some embodiments, the second temperature may be between about 70° C. and about 150° C., or more specifically between about 80° C. and about 120° C.

In the steps 140 and 150, the oxygen-containing gas may be supplied at a flow rate of between about 50 sccm and about 3,000 sccm, or more specifically between about 100 sccm and about 1,500 sccm.

In another embodiment, the vacuum UV radiation may be applied in different reaction chamber from the reaction chamber in which the silicon nitride film is converted into the silicon oxide film while supplying the oxygen-containing gas therein, after transferring the substrate thereto.

Optionally, the vacuum UV radiation may be applied after the conversion step 150 to further enhance the photo-conversion efficiency into the oxide film.

In the step 160, whether the film reaches the target thickness or not may be checked. The steps from 120 to 150 may be carried out once or repeated a plurality of times (M≥1). Then the substrate processing process may end (at the step 180).

Optionally, a film densification 170 may be further carried out to densify the silicon oxide film.

The film densification may be carried out by a thermal treatment. The thermal treatment may be carried out at between about 50° C. and about 800° C., or more specifically between about 100° C. and about 600° C. for about 300 seconds to about 3,000 seconds.

In some embodiments, the thermal treatment may be carried out while supplying a treatment gas. The treatment gas may comprise at least one of inert gas, O₂, O₃, H₂O, H₂O₂, N₂, or a mixture thereof. For instance, the treatment gas may be supplied at a flow rate of between about 200 sccm and about 5,000 sccm, more specifically between about 500 sccm and 2000 sccm.

A treatment gas with more oxygen may improve a film quality. The oligomeric silicon source may comprise a hydrogen, resulting in the hydrogen constituents in the film. Thus, the treatment gas with more oxygen may provide enough amount of oxygen to the film, resulting in removing the hydrogen from the film and improving the film quality (e.g., a film purity, a wet etch rate etc.).

For instance, at least one of H₂O₂, O₃, or a mixture thereof may be supplied for the thermal treatment during the film densification step 170. Therefore, Si—OH and/or N—H bonding may be reduced in the film, while Si—O bonding may increase in the film. In some embodiments, 1 to 10% concentration of H₂O₂ may be supplied.

In another embodiment of the present disclosure, the thermal treatment may be carried out in another reaction chamber different from the reaction chambers in which the film deposition and the conversion are carried out.

In some embodiments, the film densification may be carried out by a plasma treatment. The plasma treatment may be carried out by applying a power while supplying a treatment gas. The treatment gas may comprise at least one of H₂, He, or a mixture thereof and the power of 300 W to 700 W may be applied to activate the treatment gas.

The treatment gas for the plasma treatment may be supplied at a flow rate of between about 50 sccm and about 5,000 sccm, more specifically between about 500 sccm and about 2,000 sccm.

The plasma treatment may be carried out at between about 50° C. and 800° C., or more specifically between about 100° C. and about 600° C. The plasma treatment may be carried out in different reaction chamber from a reaction chamber in which a silicon nitride film is formed and converted into a silicon oxide film.

In some embodiments, the film densification may be performed by a plasma treatment, followed by a thermal treatment. The plasma treatment and the thermal treatment may be carried out in-situ in the same reaction chamber.

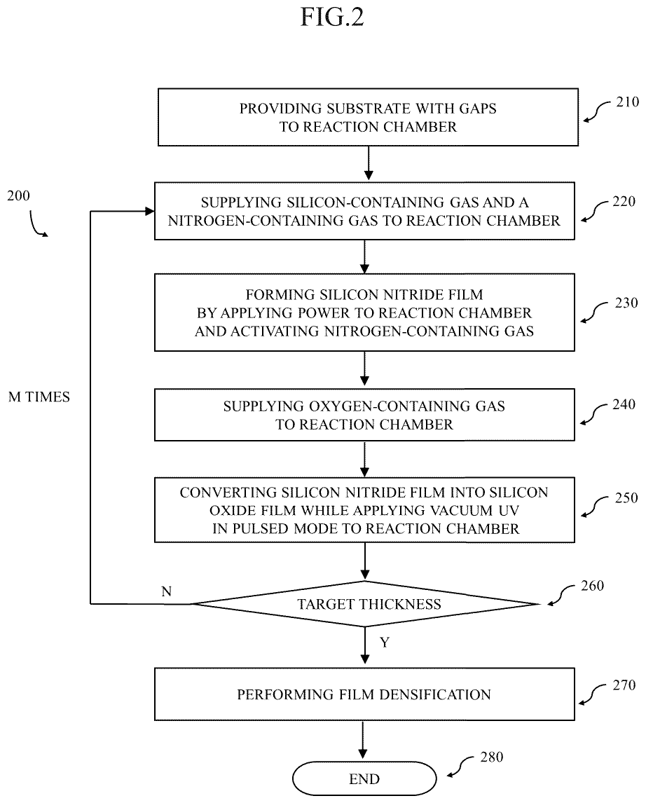

FIG. 2 illustrates a substrate processing method according to another embodiment of the present disclosure.

In the step 210, a substrate may be introduced to the reaction chamber.

In the step 220, a silicon-containing gas as a silicon source and a nitrogen-containing gas as a nitrogen source may be supplied to a reaction chamber. The silicon-containing gas may comprise an oligomeric silicon source having a flowability.

In the step 230, a power may be applied to the reaction chamber to activate the nitrogen-containing gas. The activated nitrogen-containing gas may react with the silicon-containing gas to form a flowable silicon nitride film. The steps 220 and 230 may be carried out at a first temperature.

In the step 240, an oxygen-containing gas as an oxygen source may be supplied to the reaction chamber. The oxygen source may comprise at least one of O₂, O₃, or a mixture thereof. The supplied oxygen source may infiltrate into the silicon nitride film, converting at least a portion of the silicon nitride film into the silicon oxide film. The silicon oxide film may comprise at least one of SiO, SiCO, or a mixture thereof.

In the step 250, a vacuum UV radiation may be applied to the silicon nitride film in a pulsed mode while the oxygen-containing gas is supplied continuously in order to improve the conversion efficiency into silicon oxide film. The steps 240 and 250 of FIG. 1 may be carried out at a second temperature.

In the step 250, a vacuum UV radiation may be applied in a pulsed mode, contrary to the step 150 of FIG. 1 in which the vacuum UV radiation is applied in a continuous mode. In a continuous vacuum UV mode, the surface of the film may be hardened first and the internal conversion within the film may be prevented.

In contrast, in a pulsed vacuum UV mode, the reaction of oxygen molecules in the film with the UV light may be further facilitated and the conversion may be carried out more uniformly from the upper portion to the bottom portion. Thus, the application of vacuum UV in a pulsed mode may improve a uniformity of film properties by depth in the gap.

As described above, the vacuum UV strongly excites the oxygen molecules. Therefore, the conversion rate may be faster than using the conventional UV light, leading to a through-put improvement.

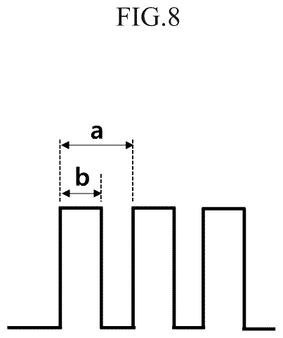

The duty ratio of the vacuum UV pulsing mode may be 20% or less. FIG. 8 illustrates the definition of duty ratio. The duty ratio is defined as the ratio of b to a. In some embodiments, the duty ratio of the vacuum UV pulsing mode may be 5% in which the ‘a’ is 60 seconds and the ‘b’ is 3 seconds.

On the other hands, when applying the vacuum UV radiation, an intensity thereof may be in a range of between about 80 mW/cm² and about 120 mW/cm².

Optionally, the vacuum UV radiation may be applied after the conversion step 250 to further enhance the photo-conversion efficiency into the oxide film.

In the step 260, whether the film reaches the target thickness or not may be checked. The steps from 220 to 250 may be carried out once or repeated a plurality of times (M≥1). Then the substrate processing process may end (at the step 280).

Optionally, a film densification 270 may be further carried out to densify the silicon oxide film.

The film densification may be carried out by a thermal treatment. The thermal treatment may be carried out at between about 50° C. and about 800° C., or more specifically between about 100° C. and about 600° C. for about 300 seconds to about 3,000 seconds. In some embodiments, the thermal treatment may be carried out while supplying a treatment gas. The treatment gas may comprise at least one of inert gas, O₂, O₃, H₂O, H₂O₂, N₂, or a mixture thereof. In another embodiment of the present disclosure, the thermal treatment may be carried out in another reaction chamber different from the reaction chambers in which the film deposition and the conversion may be carried out.

A treatment gas with more oxygen may improve film quality. The oligomeric silicon source may comprise a hydrogen, resulting in the hydrogen constituents in the film. Thus, the treatment gas with more oxygen may provide enough amount of oxygen to the film, resulting in removing the hydrogen from the film and improving the film quality (e.g., a film purity, a wet etch rate etc.).

For instance, at least one of H₂O₂, O₃, or a mixture thereof may be supplied for the thermal treatment during the film densification step 270. Therefore, Si—OH and/or N—H bonding may be reduced in the film, while Si—O bonding may increase in the film. In some embodiments, 1 to 10% concentration of H₂O₂ may be supplied.

In some embodiments, the film densification may be carried out by a plasma treatment. The plasma treatment may be carried out by applying a power while supplying a treatment gas. The treatment gas may comprise at least one of H₂, He, or a mixture thereof and the power of 300 W to 700 W may be applied to activate the treatment gas.

The plasma treatment may be carried out at between about 50° C. and 600° C., or more specifically between about 100° C. and about 500° C. The plasma treatment may be carried out in different reaction chamber from a reaction chamber in which a silicon nitride film is formed and converted into a silicon oxide film.

In some embodiments, the film densification may be performed by a plasma treatment, followed by a thermal treatment. The plasma treatment and the thermal treatment may be carried out in-situ in the same reaction chamber.

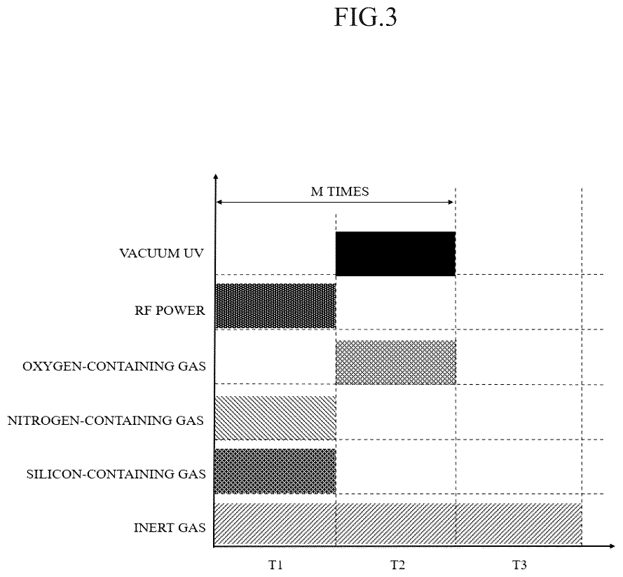

FIG. 3 illustrates a timing graph for the substrate processing method according to the embodiment of the present disclosure.

A substrate processing method according to FIG. 3 may correspond to FIG. 1. The step T1 may correspond to the steps 120 and 130 of FIG. 1. In the step T1, a silicon nitride film may be formed by supplying a silicon-containing gas and a nitrogen-containing gas and applying a RF power to the reaction chamber. The step T1 may be carried out for between about 10 seconds and about 60 seconds.

The step T2 may correspond to the steps 140 and 150 of FIG. 1. In the step T2, the silicon nitride film may be converted into a silicon oxide film by supplying an oxygen-containing gas thereto and activating the oxygen-containing gas by applying a vacuum UV radiation. As aforementioned, a process pressure may be 100 Torr or less during the step T2 in order to maintain the wavelength of the vacuum UV at 200 nm or less. Therefore, the photo-conversion efficiency of the vacuum UV may be improved. The step 2 may be carried out for between about 300 seconds and about 1,800 seconds.

On the other hand, when applying the vacuum UV radiation, an intensity thereof may be in a range of between about 80 mW/cm² and about 120 mW/cm².

The steps T1 and T2 may be carried out once or repeated a plurality of times (M≥1). After that, in the step T3, a thermal treatment may be carried out optionally and the silicon oxide film may be hardened and densified. The step T3 may correspond to the step 170 of FIG. 1. The thermal treatment may be carried out while supplying a treatment gas such as inert gas, O₂, O₃, H₂O, H₂O₂, and N₂, or a mixture thereof. The step T3 may be carried out for between about 300 seconds and about 3,000 seconds.

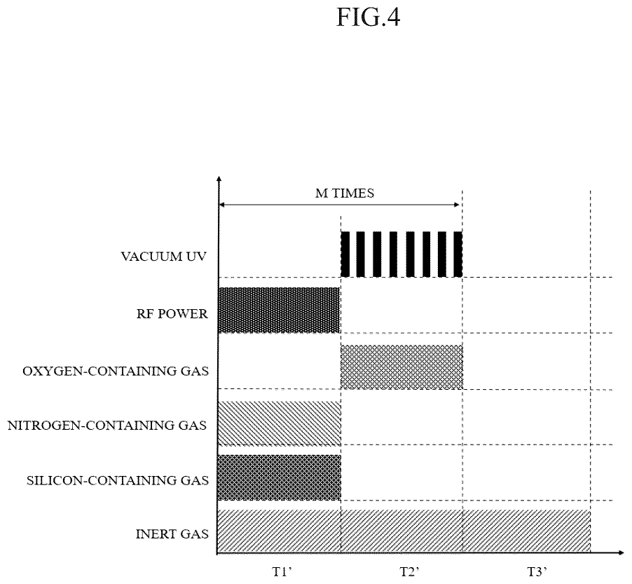

FIG. 4 illustrates a timing graph for the substrate processing method according to the embodiment of the present disclosure.

A substrate processing method according to FIG. 4 may correspond to FIG. 2. The step T1′ may correspond to the steps 220 and 230 of FIG. 2. In the step T1′, a silicon nitride film may be formed by supplying silicon-containing gas and a nitrogen-containing gas and applying a RF power to the reaction chamber.

The step T2′ may correspond to the steps 240 and 250 of FIG. 2. In the step T2′, the silicon nitride film may be converted into a silicon oxide film by supplying an oxygen-containing gas thereto and activating the oxygen-containing gas by applying a vacuum UV radiation. Contrary to FIG. 3, in FIG. 4, the vacuum UV radiation may be applied in a pulsed mode. The duty ratio of the vacuum UV pulsing mode may be 20% or less.

As aforementioned, a process pressure may be 100 Torr or less during the step T2′ in order to maintain the wavelength of the vacuum UV radiation at 200 nm or less. Therefore, the photo-conversion efficiency of the vacuum UV radiation may be improved.

On the other hand, when applying the vacuum UV radiation, an intensity thereof may be in a range of between about 80 mW/cm² and about 120 mW/cm².

The steps T1′ and T2′ may be carried out once or repeated a plurality of times (M≥1). After that, in the step T3′, a thermal treatment may be carried out optionally and the silicon oxide film may be hardened and densified. The step T3′ may correspond to the step 270 of FIG. 2. The thermal treatment may be carried out while supplying a treatment gas. The treatment gas supplied during the thermal treatment may comprise at least one of inert gas, O₂ O₃, H₂O, H₂O₂, N₂, or a mixture thereof. The step T3′ may be carried out for between about 300 seconds and about 3,000 seconds.

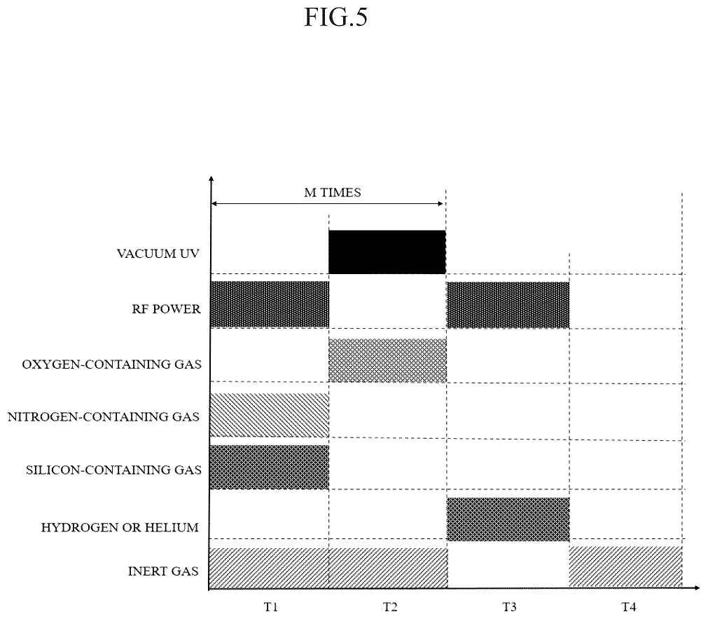

FIG. 5 illustrates a timing graph for the substrate processing method according to the embodiment of the present disclosure. FIG. 5 may be another embodiment of FIG. 3.

In the step T1 of FIG. 5, a silicon nitride film may be formed by supplying a silicon-containing gas and a nitrogen-containing gas and applying a RF power to the reaction chamber.

In the step T2 of FIG. 5, the silicon nitride film may be converted into a silicon oxide film by supplying an oxygen-containing gas thereto and activating the oxygen-containing gas by applying a vacuum UV radiation. In some embodiments, in the step T2 of FIG. 5, the vacuum UV may be supplied in the pulsed mode.

In the step T3 of FIG. 5, a plasma treatment may be carried out to densify the silicon oxide film. The plasma treatment may be carried out by applying a power while supplying a treatment gas. The treatment gas supplied in the step T3 may comprise at least one of H₂, He, or a mixture thereof.

In the step T4 of FIG. 5, a thermal treatment may be carried out to further densify the silicon oxide film. The thermal treatment may be carried out while supplying a treatment gas. The treatment gas supplied in the step T4 may comprise at least one of inert gas, O₂, O₃, H₂O, H₂O₂, N₂, or a mixture thereof.

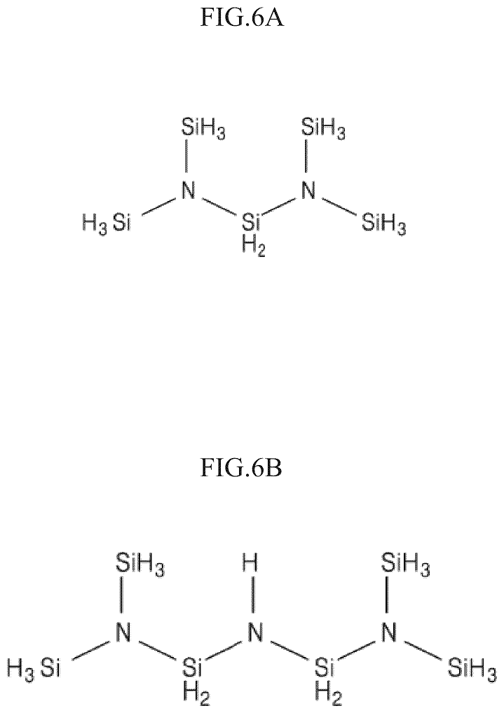

FIG. 6A shows a molecular structure of dimer-TSA comprising of two chain structures containing monomer-TSAs. FIG. 6B shows a molecular structure of trimer-TSA comprising of three chain structures containing monomer-TSAs.

FIG. 7 illustrates a reaction mechanism of the method according to the embodiment of the present disclosure.

In FIG. 7, trimer-TSA sources flow along the surface of the substrate. Trimer-TSA sources undergoes an oligomerization and a condensation to form a cross-linking network structure under NH₃ plasma conditions.

The supply of nitrogen source may facilitate the cross-linking in the oligomerization process. In more detail, the silicon nitride film may contain dangling bonds such as Si—H (denoted as ‘A’) and N—H (denoted as ‘B’) as shown in FIG. 7. Those dangling bonds may result in micropores within the film, leading to voids and deterioration of film strength. Therefore, the supplied nitrogen source may react with the hydrogen atoms and remove them and prevent the void formation.

The nitrogen source may also further facilitate the oligomerization, the condensation, and the formation of cross-linking network structure among source molecules by removing hydrogen atoms.

FIGS. 9A to 9E illustrate a flowable gap fill process according to the embodiment of the present disclosure.

In FIG. 9A, a silicon-containing gas may be supplied to the substrate having a gap. The silicon-containing gas may have a fluidity and the source molecules may not be too simple and too complicated. For instance, an oligomeric silicon source of which molecules may have 2 to 10 chain structures may be supplied.

In FIG. 9B, the silicon-containing gas may keep flowing along the surface of the substrate and the source molecules may bond each other and form a chain structure having about 10 chains (this is referred to as oligomerization). The bonding between silicon source molecules may continue and a hydrogen atom may be removed as a by-product from the source molecule structures, leading to an enhancement of the chain structure (this is referred to as condensation).

In FIG. 9B, a nitrogen-containing gas may be supplied additionally and activated by applying a power thereto. For instance, NH₃ may be supplied and NH₃ plasma may be generated by the power. The activated nitrogen source may react with the silicon sources and form a flowable silicon nitride film. In addition, the nitrogen source may further remove dangling-bonded hydrogen atoms from the film, therefore, the oligomerization and the condensation of the film and the formation of cross-linking structure may be further facilitated.

The supply of nitrogen source has another technical benefit that by removing the dangling-bonded hydrogen, the formation of micropore and void in the film may be prevented. In some embodiments, the steps FIG. 9A and FIG. 9B may be carried out simultaneously.

In FIG. 9C, an oxygen-containing gas may be supplied and convert the silicon nitride film. As aforementioned, a vacuum UV radiation may be applied to excite the oxygen source. In some embodiments, a vacuum UV radiation may be applied in a pulsed mode for uniform conversion across the film.

In FIG. 9D, as the process continues, the oligomerization and the condensation may be enhanced and the cross-linking network structure may be formed. The steps FIG. 9A to FIG. 9D may be carried out once or repeated a plurality of times.

In FIG. 8E, a thermal treatment may be performed to harden and densify the film.

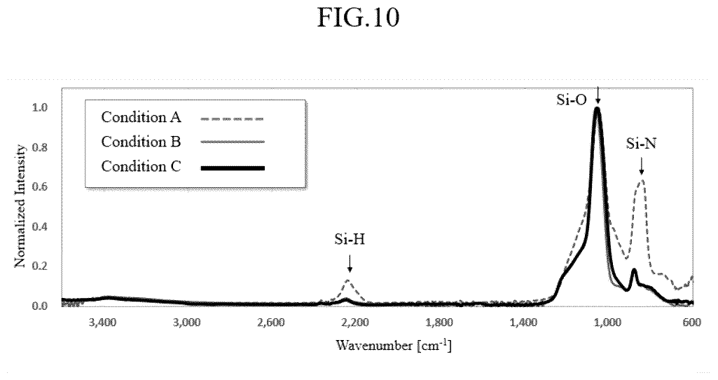

FIG. 10 illustrates an IR (Infrared Spectroscopy) analysis data showing a film composition according to the conversion conditions.

Table 1 shows three conversion conditions into the silicon oxide film as shown in FIG. 10.

TABLE 1
conversion conditions as shown in FIG. 9

| | Conversion | Conversion | | Thermal |
|---|---|---|---|---|
| | gas | time | Vacuum UV | treatment |
| Condition A | O₃ | 10 minutes | Not applied | 450° C. |
| Condition B | O₃ | 60 minutes | Not applied | 450° C. |
| Condition C | O₃ | 10 minutes | Applied (pulsed) | 450° C. |

As shown in Table 1, in Condition A, the silicon nitride film is converted into the silicon oxide film by supplying an O₃ for 10 minutes, followed by a thermal treatment at 450° C. But the vacuum UV radiation is not applied. In FIG. 10, the peak for the Condition A shows a Si—H bonding peak, Si—O bonding peak and Si—N bonding peak. That is, the Condition A may result in insufficient conversion.

In Condition B, the silicon nitride film is converted into the silicon oxide film by supplying an O₃ for 60 minutes, followed by a thermal treatment at 450° C. But the vacuum UV radiation is not applied. In FIG. 10, the peak for the Condition B shows Si—O bonding peak and weak Si—N bonding peak, but Si—H bonding peak is not detected. That is, a long conversion time may result in sufficient conversion. However, it may increase the substrate processing time.

In Condition C, the silicon nitride film is converted into the silicon oxide film by supplying an O₃ for 10 minutes, followed by a thermal treatment at 450° C. In Condition C, contrary to the Condition A and the Condition B, the vacuum UV radiation is applied in a pulsed mode. In FIG. 10, the peak for the Condition C shows Si—O bonding peak and weak Si—N bonding peak, but Si—H bonding peak is not detected, the same as the Condition B. That is, although the vacuum UV radiation is applied for a short time (e.g., 10 minutes), it results in sufficient conversion and the film quality is the same as the film quality when the conversion time is long (e.g., 60 minutes) in which a conversion gas is supplied without applying the vacuum UV radiation. Therefore, using the vacuum UV radiation in conversion step has a technical benefit that the substrate processing time is reduced significantly without deteriorating the conversion efficiency and lowering the film quality.

Table 2 shows test conditions for flowable gap fill process according to the

TABLE 2
test conditions for flowable gap fill process

| Step | Time | Test conditions | | |
|---|---|---|---|---|
| Deposition | 10 seonds to | Gas condition | Source carrier | 300 to 3,000 |
| | 60 seconds | | Ar (sccm) | (Preferably 500 to 2,000) |
| | | | Purge Ar (sccm) | 300 to 2,500 |
| | | | | (Preferably 500 to 2,000) |
| | | | Reactant (NH₃) | 10 to 100 |
| | | | (sccm) | (Preferably 20 to 50) |
| | | Plasma | RF power (W) | 40 to 200 |
| | | condition | | (Preferably 50 to 150) |
| | | | RF frequency | 10 to 60 |
| | | | (MHz) | |
| | | Process pressure (Torr) | | 1 to 9 |
| | | Process temperature (° C.) | | 100° C. or less |
| | | | | (Preferably 30 to 70) |
| | | Silicon source | | Oligomeric silicon |
| | | | | source, or silazane |
| Conversion | 20 seconds to | Gas condition | O₂ (sccm) | 50 to 3,000 |
| | 1,800 seconds | | | (Preferably 100 to 1,500) |
| | | | O₃ concentration | 100 to 500 |
| | | | (g/m³) | (Preferably 250 to 350) |
| | | Process pressure (Torr) | | 100 Torr or less |
| | | | | (Preferably 1 to 90) |
| | | Process temperature (° C.) | | 70 to 150 |
| | | | | (Preferably 80 to 120) |
| | | VUV | Duty ratio (%) | 20 or less |
| | | conditions | Intensity | 80 to 120 |
| | | | (mW/cm²) | (Preferably 90 to 100) |
| Densification | 300 seconds to | Thermal treatment | Ar or O₂ or N₂ | 200 to 5,000 |
| | 3,000 seconds | condition | (sccm) | (Preferably 500 to 2,000) |
| | | Plasma treatment | H₂ or He | 50 to 5,000 |
| | | condition | (sccm) | (Preferably 500 to 2,000) |
| | | | RF power | 300 W to 700 W |

| Process pressure (Torr) | 1 to 115 |
|---|---|
| | (Preferably 1 to 100) |
| Process temperature (° C.) | 50 to 600 |

(Preferably 100 to 500)

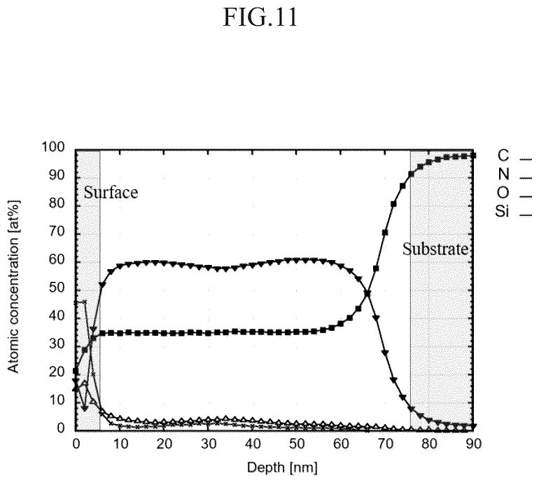

FIG. 11 illustrates an XPS (X-ray Photoelectron Spectroscopy) analysis data showing a film composition according to the embodiment of the disclosure.

In FIG. 11, a silicon nitride film is converted into a silicon oxide film by supplying an oxygen gas, while applying a vacuum UV radiation according to the embodiment of the present disclosure. As shown in FIG. 11, the film has a stoichiometrically-complete film composition in which a Si:O ratio is 1:2, and the composition of carbon and nitrogen is less than 5%.

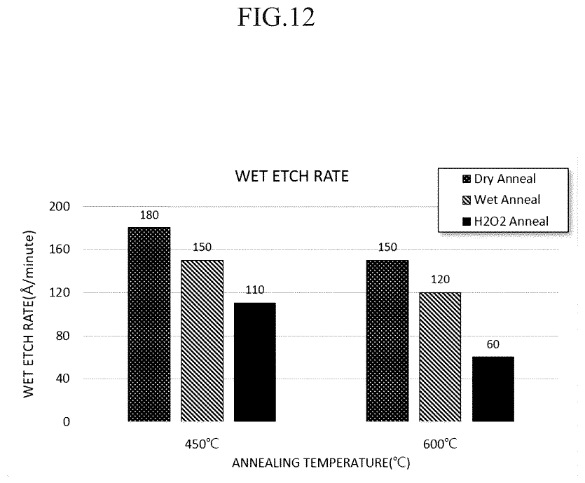

FIG. 12 illustrates a wet etch rate of SiO film depending on the thermal treatment conditions.

As shown in FIG. 12, the wet etch rate (WER) of SiO film may be measured for three thermal treatment conditions (i.e., dry annealing, wet annealing, and H₂O₂ annealing at 450° C. and 600° C. respectively). The wet etch rate may be measured by dipping the substrate coated with the SiO film which was thermally treated into a hydrofluoric acid solution diluted 100:1 in deionized water(dHF) for 1 minute and measuring the SiO film thickness which are etched out. In FIG. 12, the WER is an average value measured after performing etching the film in the dHF solution three times.

In FIG. 12, the dry annealing may be performed by supplying N₂ for 30 minutes at 450° C. and 600° C. respectively. The wet annealing may be performed by supplying H₂O (steam) for 30 minutes at 450° C. and 600° C. respectively. The H₂O₂ annealing may be performed by supplying H₂O₂ for 30 minutes at 450° C. and 600° C. respectively.

In FIG. 12, the SiO film treated under the H₂O₂ annealing has the lowest wet etch rate, resulting in forming the hardest SiO film compared to other annealing conditions.

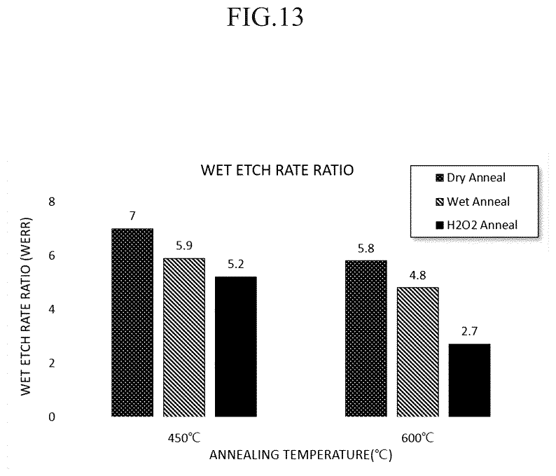

FIG. 13 illustrates a wet etch rate ratio (WERR) of SiO film depending on the thermal treatment conditions. The WERR is a ratio of a wet etch rate of SiO film to a wet etch rate of SiO film formed thermally at 1,000° C.

In FIG. 13, the SiO film treated under H₂O₂ annealing may have the lowest wet etch rate ratio, resulting in forming the hardest SiO film compared to other annealing conditions.

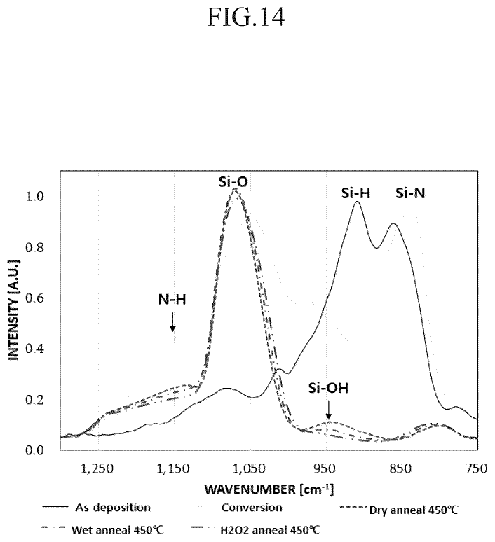

FIG. 14 illustrates an Infrared Spectroscopy Analysis results showing a bonding structure of the SiO film depending on the thermal treatment conditions at 450° C.

As shown in FIG. 14, a N—H peak (at around 1,150 cm⁻¹) and a Si—OH peak (at around 950 cm⁻¹) shows the lowest intensity when a H₂O₂ annealing is performed compared to a dry annealing and a wet annealing. That is, the H₂O₂ annealing may be more effective in removing a hydrogen from the film and improving the film quality (e.g., a film purity, a wet etch rate etc.).

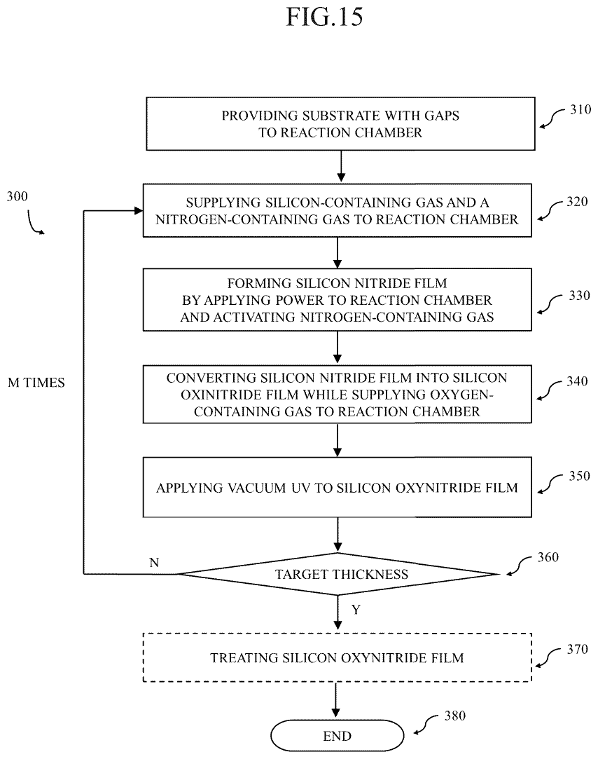

FIG. 15 illustrates a substrate processing method according to another embodiment of the present disclosure. The method of FIG. 15 may be performed at 70° C. or below.

In the step 310 of the substrate processing method 300, a substrate a substrate may be provided to a reaction chamber. In more detail, the substrate may be loaded onto a susceptor mounted on a heating block. The heating block may provide a heat energy to heat the substrate to a process temperature. The substrate may have a semiconductor circuit formed thereon including 3D structures and gaps. In some embodiment of the present disclosure, the depth of the gap may be 200 nm or less. The reaction chamber may comprise an equipment in which the substrate is processed. In the reaction chamber, a deposition, a gap fill, an etch, or any other substrate processing process using a gas activation source such as plasma and/or UV may be performed on the substrate.

In the step 320, a silicon-containing gas as a silicon source and a nitrogen-containing gas as a nitrogen source may be supplied to a reaction chamber. The silicon-containing gas may comprise an oligomeric silicon source that may have flowability.

The silicon-containing gas may comprise at least one of comprises at least one of dimer-trisilylamine, trimer-trisilylamine, tetramer-trisilylamine, pentamer-trisilylamine, hexamer-trisilylamine, heptamer-trisilylamine, octamer-trisilylamine, 2,2,4,4,6,6-hexamethylcyclotrisilazane, 1,1,1,3,3,3-hexamethyl disilazane, 1,3-divinyl-1,1,3,3-tetramethyldisilazane and 1,1,3,3-tetramethyldisilazane, or a mixture thereof.

The nitrogen-containing gas may comprise at least of N₂, N₂O, NO₂, NH₃, NH₄, N₂H₂, N₂H₄, or a mixture thereof.

In the step 330, a power may be applied to the reaction chamber to activate the nitrogen-containing gas. The activated nitrogen-containing gas may react with the silicon-containing gas to form a flowable silicon nitride (SiN) film. The steps 320 and 330 may be carried out simultaneously. The power may be applied in situ or remotely. The power may be in a range of between about 10 W and about 1,000 W.

In the step 340, converting the silicon nitride film into a silicon oxynitride film (SiON) may be performed while supplying an oxygen-containing gas to the reaction chamber. The oxygen-containing gas may comprise an ozone (O₃). A concentration of the ozone may be in a low range of between about 200 g/m³ and about 400 g/m³.

In the step 350, a vacuum UV radiation may be applied to the silicon nitride film while an inert gas (e.g., Ar) is supplied. In the step 350, the oxygen-containing gas may not be supplied to prevent the silicon nitride film from being fully converted into a silicon oxide film. In other word, the silicon nitride film may be partially converted into the silicon oxide film, resulting in forming a silicon oxynitride film.

A low substrate processing temperature of about 70° C. or below may cause the ozone to be less active. A low concentration of ozone of between about 200 g/m³ and about 400 g/m³ may provide less oxygen to the silicon nitride film. Therefore, the silicon nitride film may not be fully converted into a silicon oxide film, resulting in a silicon oxynitride film being formed.

As a result, the silicon oxynitride film may be formed. An intensity of the vacuum UV radiation may be in a range of between about 80 mW/cm² and about 120 mW/cm².

In the step 360, whether the silicon oxynitride film reaches the target thickness or not may be checked. The steps from 320 to 350 may be carried out once or repeated a plurality of times (M≥1). Then the substrate processing process may end (at the step 380).

Optionally, in the step 370, treating the silicon oxynitride film may be further carried out to treat the silicon oxynitride film (e.g., annealing, densification etc.). Treating the silicon oxynitride film may be performed thermally or by applying a power while supplying at least one of Ar, O₂, N₂, or the mixture thereof.

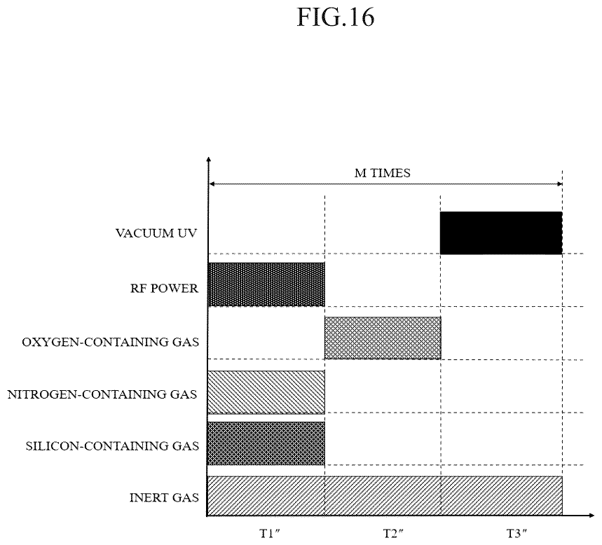

FIG. 16 illustrates a timing graph of for the substrate processing method to form a silicon oxynitride film according to an embodiment of the present disclosure. FIG. 16 may correspond to FIG. 15.

In the step T1″ of FIG. 16, a silicon nitride film may be formed by supplying a silicon-containing gas and a nitrogen-containing gas while a power is applied to a reaction chamber.

In the step T2″, the silicon nitride film may be converted into a silicon oxynitride film by supplying an oxygen-containing gas. The oxygen-containing gas may comprise an ozone (O₃).

In the step T3″, a vacuum UV radiation may be applied to the silicon oxynitride film. In the step T3″, the oxygen-containing gas may not be supplied to prevent the silicon nitride film from being fully converted into a silicon oxide film. Therefore, the silicon nitride film may be partially converted into the silicon oxide film. In other word, a silicon oxynitride film may be formed.

According to an embodiment of the present disclosure, a wet etch rate of the silicon oxynitride film may be determined by a ratio of a conversion time to convert the silicon nitride film into the silicon oxynitride film to a vacuum UV radiation treatment time.

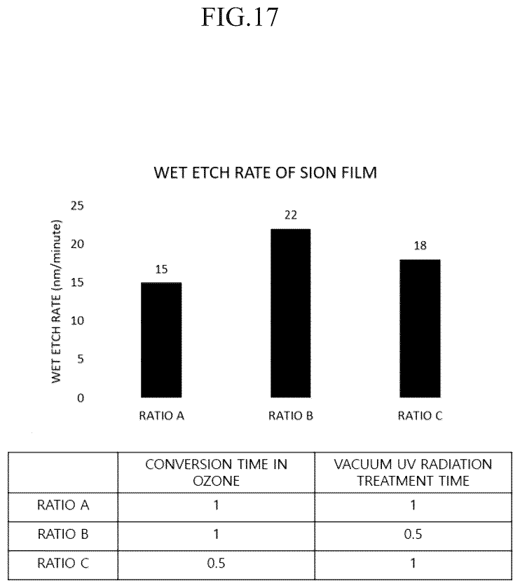

FIG. 17 illustrates a wet etch rate of a silicon oxynitride film according to a ratio of the conversion time in ozone (O₃) to the Vacuum UV radiation treatment time. The wet etch may be performed in a hydrofluoric acid solution diluted 200:1 in deionized water(dHF) for 180 seconds.

As shown in FIG. 17, the wet etch rate of the silicon oxynitride film may be about 15 nm/minute at the ratio of 1:1. Thus, the wet etch ratio may be controlled by the ratio between the conversion time and the Vacuum UV radiation time.

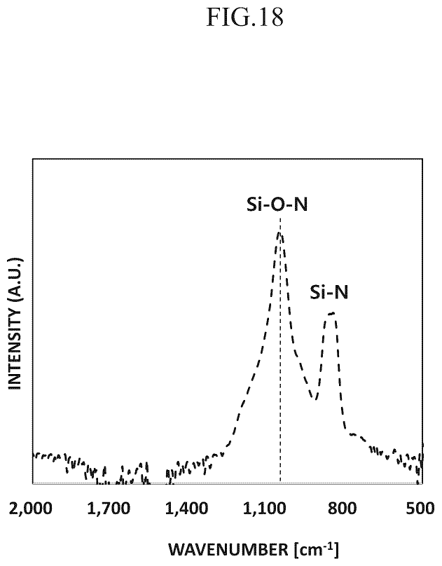

FIG. 18 illustrates an Infrared Spectroscopy Analysis results showing a bonding structure of a silicon oxynitride film formed according to an embodiment of the present disclosure. As shown in FIG. 18, a peak for the silicon oxynitride (SiON) film is shown at around 1,100 cm⁻¹.

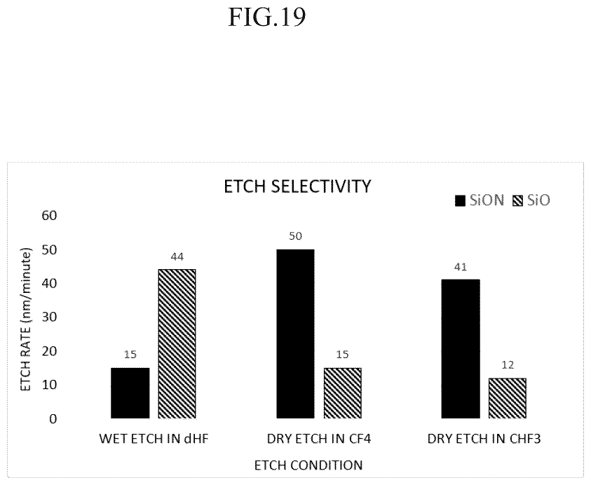

FIG. 19 illustrates an etch selectivity between a silicon oxynitride film and a silicon oxide film depending on an etch condition.

In FIG. 19, a wet etch may be performed in a hydrofluoric acid diluted 200:1 in deionized water(dHF) for 180 seconds at 20° C. A dry etch in CF₄ may be performed by supplying a CF₄ etching gas to the reaction chamber while applying a 100 W of power for 30 seconds to the reaction chamber at 60 mTorr at 50° C. A dry etch in CHF₃ may be performed by supplying a CHF₃ etching gas to the reaction chamber while applying a 100 W of power for 30 seconds to the reaction chamber at 60 mTorr at 50° C.

As shown in FIG. 19, the etch rate shows a big difference between the SiON film and the SiO film at each etch condition. The etch rate also shows a big difference between the same film depending on the etch condition. That is, an embodiment of the present disclosure may be applied to a substrate processing method which requires a big etch selectivity in a certain etching condition. Therefore, a selective etching process may be carried out on non-planar surface of a substrate, for instance.

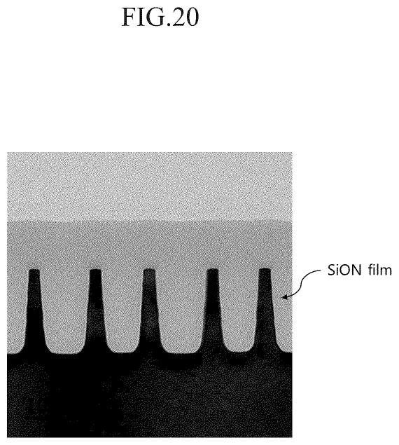

FIG. 20 shows a Scanning Electron Microscope (SEM) image of SiON film filling a gap. As shown in FIG. 20, the gap may be filled with the SiON film without a void.

Table 3 shows test conditions for filling a gap with flowable SiON film according to an embodiment of the present disclosure.

TABLE 3
test conditions for filling a gap with flowable SiON film

| Step | Time | Test conditions | | |
|---|---|---|---|---|
| Deposition | 10 seonds to | Gas condition | Source carrier Ar | 300 to 3,000 |
| | 1,000 seconds | | (sccm) | (Preferably 500 to 2,000) |
| | | | Purge Ar (sccm) | 300 to 2,500 |
| | | | | (Preferably 500 to 2,000) |
| | | | Reactant (NH₃) | 10 to 100 |
| | | | (sccm) | (Preferably 20 to 50) |
| | | Plasma | RF power (W) | 10 to 1,000 |
| | | condition | | (Preferably 40 to 800) |
| | | | RF frequency | 10 to 60 |
| | | | (MHz) | |
| | | Process pressure (Torr) | | 1 to 9 |
| | | Process temperature (° C.) | | 70° C. or below |
| | | | | (Preferably 30° C. to 70° C.) |
| | | Silicon source | | Oligomeric silicon |
| | | | | source, or silazane |
| Conversion | 100 seconds to | Gas condition | Ar (sccm) | 500 to 5,000 |
| | 1,000 seconds | | | (Preferably 2,000 to 4,000) |
| | | | O₃ (sccm) | 500 to 5,000 |
| | | | | (Preferably 2,000 to 4,000) |
| | | | O₃ concentration | 100 to 500 |
| | | | (g/m³) | (Preferably 200 to 400) |
| | | Process pressure (Torr) | | 200 Torr or less |
| | | | | (Preferably 50 to 100) |
| | | Process temperature (° C.) | | 70° C. or below |
| | | | | (Preferably 30° C. to 70° C.) |
| VUV | 50 seconds to | Gas condition | Ar (sccm) | 500 to 5,000 |
| treatment | 1,000 seconds | | | (Preferably 1,000 to 4,000) |

| VUV condition: Intensity | 80 to 120 |
|---|---|
| (mW/cm²) | (Preferably 90 to 100) |
| Process pressure (Torr) | 200 Torr or less |
| | (Preferably 50 to 100) |
| Process temperature (° C.) | 70° C. or below |

(Preferably 30° C. to 70° C.)

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

1. A method of filling a gap of a substrate, the method comprising:
forming a flowable silicon nitride film in the gap at a first temperature comprising:
supplying a silicon-containing gas and a nitrogen-containing gas to a reaction chamber; and
applying a power to the reaction chamber to activate the nitrogen-containing gas,
wherein the silicon-containing gas reacts with the activated nitrogen-containing gas to form the silicon nitride film;
converting the silicon nitride film into a silicon oxide film at a second temperature comprising:
continuously supplying an oxygen-containing gas to the reaction chamber; and
applying a Vacuum UV radiation to the silicon nitride film;
wherein the first temperature is different from the second temperature.

2. The method of claim 1, wherein converting the silicon nitride film into the silicon oxide film is carried out at a pressure of 100 Torr or less.

3. The method of claim 2, wherein the Vacuum UV radiation is applied in a pulsed mode.

4. The method of claim 3, wherein a duty ratio of the pulsed mode is 20% or less.

5. The method of claim 1, wherein an intensity of the Vacuum UV radiation is in a range of between about 80 mW/cm² and about 120 mW/cm².

6. The method of claim 1, wherein the first temperature is about 100° C. or less.

7. The method of claim 1, wherein the second temperature is between about 70° C. and about 150° C.

8. The method of claim 7, wherein the second temperature is between about 80° C. and about 120° C.

9. The method of claim 1, wherein the silicon nitride film comprises at least one of SiN, SiCN, or a mixture thereof.

10. The method of claim 1, wherein the silicon-containing gas comprises at least one of dimer-trisilylamine, trimer-trisilylamine, tetramer-trisilylamine, pentamer-trisilylamine, hexamer-trisilylamine, heptamer-trisilylamine, octamer-trisilylamine, 2,2,4,4,6,6-hexamethylcyclotrisilazane, 1,1,1,3,3,3-hexamethyl disilazane, 1,3-divinyl-1,1,3,3-tetramethyldisilazane and 1,1,3,3-tetramethyldisilazane, or a mixture thereof.

11. The method of claim 1, wherein the nitrogen-containing gas comprises at least one of N₂, N₂O, NO₂, NH₃, NH₄, N₂H₂, N₂H₄, or a mixture thereof.

12. The method of claim 11, wherein the nitrogen-containing gas is suppled at between about 10 sccm and about 100 sccm.

13. The method of claim 12, wherein the nitrogen-containing gas is suppled at between about 20 sccm and about 50 sccm.

14. The method of claim 1, wherein the silicon oxide film comprises at least one of SiO, SiCO, or a mixture thereof.

15. The method of claim 1, wherein the oxygen-containing gas comprises at least one of O₂, O₃, or mixture thereof.

16. The method of claim 15, wherein the oxygen-containing gas is suppled at between about 50 sccm and about 3,000 sccm.

17. The method of claim 16, wherein the oxygen-containing gas is suppled at between about 100 sccm and about 1,500 sccm.

18. The method of claim 1, wherein the Vacuum UV radiation is applied in different reaction chamber from the reaction chamber in which the silicon nitride film is converted into the silicon oxide film while supplying the oxygen-containing gas therein, after transferring the substrate thereto.

19. The method of claim 1, wherein the power is in a range of between about 40 W and about 200 W.

20. The method of claim 19, wherein the power is in a range of between about 50 W and about 150 W.

21. The method of claim 1, further comprising performing a film densification to densify the silicon oxide film at a third temperature in a reaction chamber different from the reaction chambers in which the film is formed and converted, while supplying a treatment gas thereto.

22. The method of claim 21, wherein the film densification is performed by at least one of a plasma treatment, a thermal treatment, or a mixture thereof.

23. The method of claim 22, wherein the film densification is performed by the plasma treatment, followed by the thermal treatment.

24. The method of claim 21, wherein the third temperature is between about 50° C. and about 800° C.

25. The method of claim 24, wherein the third temperature is between about 100° C. and about 600° C.

26. The method of claim 22, wherein the treatment gas comprises at least one of inert gas, O₂, O₃, H₂O, H₂O₂, N₂, or a mixture thereof during the thermal treatment.

27. The method of claim 22, wherein the treatment gas comprises at least one of H₂, He, or a mixture thereof during the plasma treatment.

28. The method of claim 22, wherein a power of between about 300 W and about 700 W is applied to the reaction chamber during the plasma treatment.

29. The method of claim 1, wherein the method is carried out once or repeated a plurality of times.

30. A method of filling a gap of a substrate, the method comprising:
forming a flowable silicon nitride film in the gap comprising:
supplying a silicon-containing gas and a nitrogen-containing gas to a reaction chamber; and
applying a power to the reaction chamber to activate the nitrogen-containing gas,
wherein the silicon-containing gas reacts with the activated nitrogen-containing gas to form the silicon nitride film;
converting the silicon nitride film into a silicon oxynitride film (SiON) while supplying an oxygen-containing gas to the reaction chamber; and
applying a Vacuum UV radiation to the silicon oxynitride film.

31. The method of claim 30, wherein the method is carried out at about 70° C. or below.

32. The method of claim 30, wherein the Vacuum UV radiation is applied without supplying the oxygen-containing gas.

33. The method of claim 30, wherein the oxygen-containing gas comprises an ozone (O₃).

34. The method of claim 33, wherein a concentration of the ozone is in a range of between about 200 g/m³ and about 400 g/m³.

35. The method of claim 30, further comprising treating the silicon oxynitride film thermally by supplying at least one of Ar, O₂, N₂, or a mixture thereof.

36. The method of claim 30, further comprising treating the silicon oxynitride film by applying a power and supplying at least one of Ar, O₂, N₂, or a mixture thereof.

37. The method of claim 30, wherein a wet etch rate of the silicon oxynitride film is determined by a ratio of a time for converting the silicon nitride film into the silicon oxynitride film to a time for treating the silicon oxynitride film under the Vacuum UV radiation.

38. The method of claim 37, wherein the wet etch rate of the silicon oxynitride film is about 15 nm/minute at the ratio of 1:1.

39. The method of claim 30, wherein the silicon-containing gas comprises at least one of dimer-trisilylamine, trimer-trisilylamine, tetramer-trisilylamine, pentamer-trisilylamine, hexamer-trisilylamine, heptamer-trisilylamine, octamer-trisilylamine, 2,2,4,4,6,6-hexamethylcyclotrisilazane, 1,1,1,3,3,3-hexamethyl disilazane, 1,3-divinyl-1,1,3,3-tetramethyldisilazane and 1,1,3,3-tetramethyldisilazane, or a mixture thereof.

40. The method of claim 30, wherein the nitrogen-containing gas comprises at least one of N₂, N₂O, NO₂, NH₃, NH₄, N₂H₂, N₂H₄, or a mixture thereof.

41. The method of claim 30, wherein the power is in a range of between about 10 W and about 1,000 W.

42. The method of claim 30, wherein an intensity of the Vacuum UV radiation is in a range of between about 80 mW/cm² and about 120 mW/cm².

43. The method of claim 30, wherein the method is carried out once or repeated a plurality of times.
